(19) United States
(12) Patent Application Publication
(10) Pub. No.: US 2019/0309419 A1
(43) Pub. Date: Oct. 10, 2019

(54) HIGH TEMPERATURE GAS DISTRIBUTION ASSEMBLY

(71) Applicant: Applied Materials, Inc., Santa Clara, CA (US)

(72) Inventor: Sanjeev BALUJA, Campbell, CA (US)

(21) Appl. No.: 16/371,789

(22) Filed: Apr. 1, 2019

Related U.S. Application Data
(60) Provisional application No. 62/653,935, filed on Apr. 6, 2018.

(51) Int. Cl. C23C 16/455; C23C 16/48

(52) U.S. Cl. CPC C23C 16/45565; C23C 16/45536; C23C 16/45504; C23C 16/482

(57) ABSTRACT

The present disclosure generally relates to an apparatus for gas distribution in a substrate processing chamber. The gas distribution apparatus includes a first blocker plate, a second blocker plate, and a faceplate. The faceplate movably rests on a chamber liner partially defining a processing volume. A lamp assembly is disposed above the gas distribution assembly and tunably heats the faceplate.

### CROSS-REFERENCE TO RELATED APPLICATIONS

This application claims priority from U.S. Provisional Application Ser. No. 62/653,935, filed Apr. 6, 2018, which is hereby incorporated by reference in its entirety.

### BACKGROUND

### Field

Embodiments of the present disclosure generally relate to a faceplate for distributing a gas in substrate processing chambers.

### Description of the Related Art

In the fabrication of integrated circuits, deposition processes such as chemical vapor deposition (CVD) or atomic layer deposition (ALD) are used to deposit films of various materials upon semiconductor substrates. In other operations, a layer altering process, such as etching, is used to expose a portion of a layer for further depositions. Often, these processes are used in a repetitive fashion to fabricate various layers of an electronic device, such as a semiconductor device.

Fabricating a defect free semiconductor device is desirable when assembling an integrated circuit. The slightest contaminants or defects present in a substrate can cause major manufacturing defects within the final fabricated device. For example, contaminants present in the process gas, the process gas source, or the process gas delivery system may be deposited on the substrate, causing defects and reliability issues in the semiconductor device fabricated thereon. Accordingly, it is desirable to form a defect-free film when performing deposition or other layer altering processes. However, with conventional deposition devices, the layered films may be formed with defects and contaminants.

Therefore, there is a need in the art for apparatuses which reduce defects during device fabrication.

### SUMMARY

In one embodiment, a gas distribution apparatus is provided. The gas distribution apparatus includes a lid assembly, a window coupled to the lid assembly, a first blocker plate coupled to the lid assembly, a second blocker plate coupled to the lid assembly, and a faceplate disposed on a chamber liner. The lid assembly includes a plurality of annular members disposed in a stacked arrangement. The window, the first blocker plate, and the second blocker plate are transparent to electromagnetic radiation.

In one embodiment, a gas distribution apparatus is provided. The gas distribution apparatus includes a lid assembly, a window coupled to the lid assembly, a first blocker plate coupled to the lid assembly, a second blocker plate coupled to the lid assembly, a faceplate disposed on a chamber liner, and a gas feed tube centrally disposed through the window, the first blocker plate, and the second blocker plate. The lid assembly includes a plurality of annular members disposed in a stacked arrangement. The window, the first blocker plate, and the second blocker plate are transparent to electromagnetic radiation.

In one embodiment, an apparatus for processing a substrate is provided. The substrate processing apparatus includes a chamber having side walls and a base defining an interior volume therein, a lid assembly, a window coupled to the lid assembly, and a radiant heat source disposed adjacent to the window and external to the interior volume. The apparatus further includes a substrate support and a gas distribution assembly having a first blocker plate coupled to the lid assembly, a second blocker plate coupled to the lid assembly, and a faceplate disposed on a chamber liner.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1A illustrates a cross-sectional view of a processing chamber having a gas distribution apparatus according to one embodiment described herein.

FIG. 1B illustrates a cross-sectional view of a portion of the processing chamber of FIG. 1A according to one embodiment described herein.

FIG. 2 illustrates a cross-sectional view of a processing chamber having a gas distribution apparatus according to another embodiment described herein.

FIG. 3 illustrates a cross-sectional view of a processing chamber having a gas distribution apparatus according to another embodiment described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to an apparatus for gas distribution in a substrate processing chamber. The gas distribution apparatus includes a first blocker plate, a second blocker plate, and a faceplate. The faceplate movably rests on a chamber liner partially defining a processing volume. A lamp assembly is disposed above the gas distribution assembly and tunably heats the faceplate.

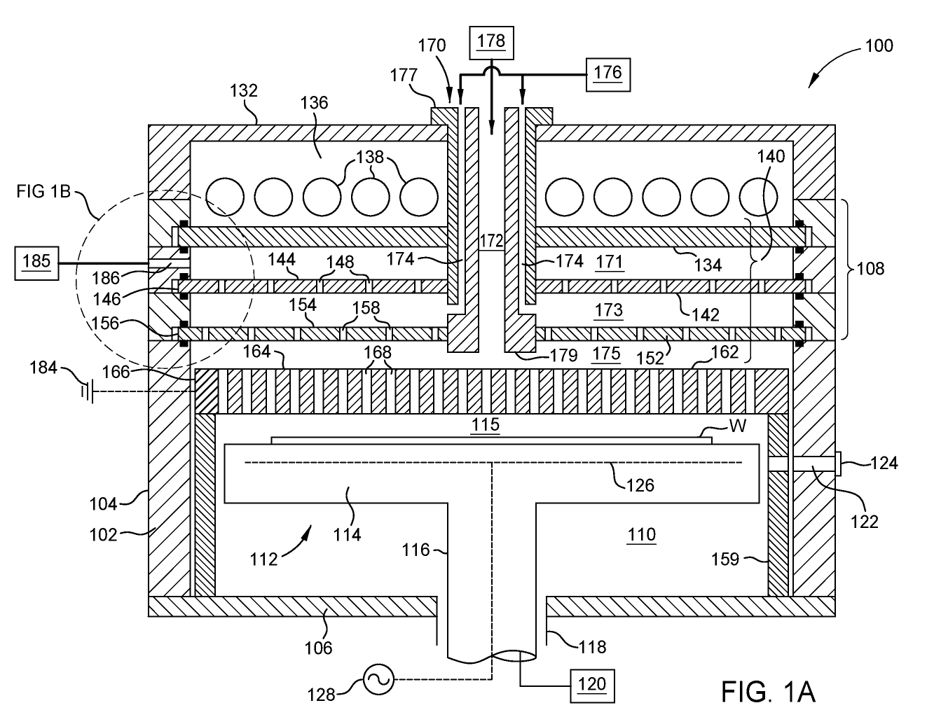

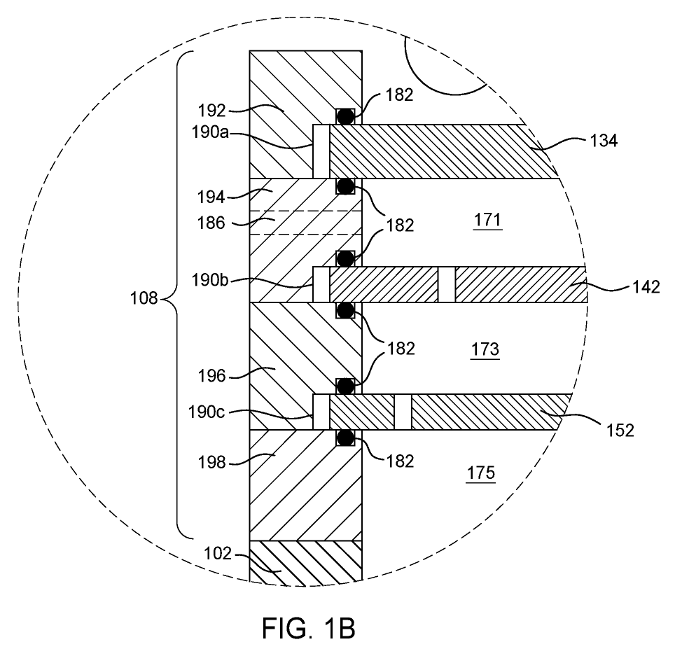

FIG. 1A illustrates a cross-sectional view of a processing chamber 100 according to one embodiment. The processing chamber 100 is generally used in deposition processes, such as atomic layer deposition (ALD), chemical vapor deposition (CVD), plasma-enhanced chemical vapor deposition (PECVD), microwave plasma-enhanced chemical vapor deposition (MPCVD), or physical vapor deposition (PVD), among others. The processing chamber 100 includes a body 102 having sidewalls 104 and a base 106 partially defining an interior volume 110 therein. An annular lid assembly 108 couples to the body 102 opposite the base 106. In some embodiments, the body 102 is formed from a metallic material, such as stainless steel or aluminum. However, the body 102 may be formed of any material suitable for use with the process being performed therein.

A substrate support 112 is disposed within a processing volume 115 opposite a gas distribution assembly 140. The substrate support 112 includes a support body 114 coupled to a support shaft 116. The support shaft 116 couples to a lower surface of the support body 114 and extends out of the body 102 through an opening 118 in the base 106. The support shaft 116 is further coupled to an actuator 120 configured to vertically actuate the support shaft 116, and the support body 114 coupled thereto, between a substrate loading position and a substrate processing position. In certain embodiments, the support shaft 116 is further configured to rotate about a vertical axis. A vacuum system (not shown) is fluidly coupled to the interior volume 110 in order to evacuate gases from the processing volume 115.

To facilitate processing of a substrate W in the processing chamber 100, the substrate W is disposed on the support body 114 opposite of the support shaft 116. A port 122 is formed in the sidewall 104 to facilitate ingress and egress of the substrate W into the processing volume 115. A door 124, such as a slit valve, is actuated to selectively enable the substrate W to pass through the port 122 to be loaded onto, or removed from, the substrate support 112. An electrode 126 is optionally disposed within the support body 114 and electrically coupled to a power source 128 through the support shaft 116. The electrode 126 is selectively biased by the power source 128 to create an electromagnetic field to chuck the substrate W to the support body 114. In certain embodiments, a heater (not shown), is disposed in the support body 114 to heat the substrate W disposed thereon.

A window 134 is coupled to the lid assembly 108 and partially defines the interior volume 110, enabling maintenance of a vacuum seal therewithin. A radiant heat source 136 is disposed outwardly (e.g., above) of the window 134. In some embodiments, the radiant heat source 130 is exposed to an external environment on upper surfaces thereof. In other embodiments, the radiant heat source 136 is encased between the window 134 and an optional upper housing 132 that couples to the lid assembly 108 and isolates the radiant heat source 136 from the external environment. The radiant heat source 136 includes a plurality of electromagnetic (EM) radiation sources 138 for heating a faceplate 162 of the gas distribution assembly 140 and/or gases provided within the interior volume 110 during processing. In some embodiments, the radiation sources 138 are irradiation lamps, such as infrared (IR) or ultraviolet (UV) lamps. In some embodiments, the radiation sources 138 are LED or UV emitters.

Any desired arrangement of the radiation sources 138 may be utilized. In certain embodiments, the radiation sources 138 are disposed in concentric rings around a central axis. The radiation sources 138 are further divided into distinct heating zones, with each heating zone controlled to emit different levels of EM radiation as desired. For example, in embodiments wherein the radiation sources 138 are disposed in concentric rings, each concentric ring of radiation sources 138 may be individually controlled to emit different levels of EM radiation, thus enabling the radiant heat source 136 to be radially tunable. By having one or more distinct heating zones, the distribution profile of EM radiation through the window 134 may be controlled.

The window 134 isolates the radiant heat source 136 from the interior volume 110. The window 134 is made of a material that is substantially transparent to the EM radiation emitted by the radiant heat source 136, which is used to heat a faceplate 162 and/or one or more process gases in the interior volume 110 during processing. For example, the window 134 is substantially transparent to infrared radiation emitted by IR radiation sources 138. The window 134 has a sufficient thickness to maintain vacuum within the interior volume 110 without cracking. In some embodiments, the window 134 is made of quartz. In other embodiments, the window 134 is made of sapphire. Other materials for the window 134 are also contemplated, including but not limited to silicon oxide, silicon oxynitride, calcium fluoride, magnesium fluoride, and aluminum oxynitride. In certain embodiments, a cooling source (not shown) is disposed adjacent to the window 134 and configured to maintain the window 134 at low temperatures during operation. The cooling source may be any suitable type of cooling source, such as a cool air distribution system or cooling fluid distribution system. During operation, the window 134 is maintained at a temperature below 250° C., such as a temperature below 200° C. For example, the window 143 is maintained at a temperature below 150° C.

The optional upper housing 132 is generally formed from a metallic material, such as stainless steel or aluminum. In certain embodiments, the upper housing 132 includes an interior surface defined by a reflective lining. The reflective lining may be used to reflect radiation emitted by the radiant heat source 136 towards the window 134. In some embodiments, the interior surface of the upper housing 132 has a parabolic or elliptical profile. In other embodiments, the interior surface of the upper housing 132 has a planar surface. The interior surface of the upper housing 132 may be shaped to provide a desired distribution profile of EM radiation through the window 134.

The gas distribution assembly 140 includes an upper blocker plate 142, a lower blocker plate 152, the faceplate 162, and a gas feed tube 170. The lower blocker plate 152 and the upper blocker plate 142 include circular distribution portions 154, 144, respectively, surrounded by annular extensions 156, 146, respectively. The lower blocker plate 152 is disposed between the faceplate 162 and the window 134 and couples to the lid assembly 108 at the annular extension 156. The upper blocker plate 142 is disposed between the lower blocker plate 152 and the window 134 and couples to the lid assembly 108 at the annular extension 146. The faceplate 162 is disposed adjacent to and facing the processing volume 115 and the substrate support 112, thus partially defining the processing volume 115. A first plenum 171 is defined between the upper blocker plate 142 and the window 134. A second plenum 173 is further defined between the upper blocker plate 142 and the lower blocker plate 152. A third plenum 175 is further defined between the lower blocker plate 152 and the faceplate 162.

The upper blocker plate 142 and the lower blocker plate 152 are made of a material that is substantially transparent to the EM radiation emitted by the radiant heat source 136, such as infrared radiation emitted by IR radiation sources 138. In certain embodiments, the upper blocker plate 142 and the lower blocker plate 152 are formed of quartz. Other materials are also contemplated, including but not limited to aluminum oxynitride, sapphire, silicon oxide, silicon oxynitride, calcium fluoride, and magnesium fluoride. It is further contemplated that the upper blocker plate 142 and the lower blocker plate 152 may be formed of the same material, or of different materials from each other.

A first plurality of apertures 148 is formed through the upper blocker plate 142 and a second plurality of apertures 158 is formed through the lower blocker plate 152. The apertures 148, 158, in conjunction with the distribution portions 154, 144, facilitate fluid communication between the first plenum 171, the second plenum 173, and the third plenum 175. In some embodiments, the apertures 148, 158 are evenly distributed across the upper blocker plate 142 and the lower blocker plate 152. In some embodiments, the apertures 148, 158 are distributed with different spacing. In still further embodiments, the apertures 148 are substantially aligned with the apertures 158. In other embodiments, the apertures 148 are unaligned with the apertures 158.

The gas feed tube 170 is centrally disposed through the optional upper housing 132, the window 134, the upper blocker plate 142, and the lower blocker plate 152. In certain embodiments, the gas feed tube 170 is formed of a ceramic material. In certain embodiments, the gas feed tube 170 is formed of quartz, sapphire, aluminum oxide, aluminum nitride, yttria or the like. The gas feed tube 170 is fluidly coupled to a first gas source 176 and a second gas source 178. The gas feed tube 170 includes a central channel 172 formed from a first end 177 to a second end 179 thereof. One or more secondary channels 174 are further disposed partially through the gas feed tube 170 and radially outward of the central channel 172. For example, the secondary channel 174 has a first opening at the first end 177 and a second opening in a sidewall of the gas feed tube 170 adjacent the second plenum 173, as depicted in FIG. 1A. The central channel 172 enables gas to flow from the second gas source 178, through the gas feed tube 170, and into the third plenum 175. The secondary channel 174 enables gas to flow from the first gas source 176, through the gas feed tube 170, and into the second plenum 173. In other embodiments, the second opening of the secondary channel 174 is adjacent to the first plenum 171, and thus the secondary channel 174 enables gas to flow from the first gas source 176 to the first plenum 171.

In one example, the first gas source 176 supplies a process gas, such as an etching gas or a deposition gas, to the interior volume 110 to etch or deposit a layer on the substrate W. Any suitable deposition gases are contemplated. In this example, the second gas source 178 supplies a cleaning gas to the interior volume 110 in order to remove particle depositions from internal surfaces of the processing chamber 100. Any suitable cleaning gases are contemplated, including but not limited to fluorine-based cleaning agents. In some embodiments, the second gas source 178 includes a remote plasma source (RPS). To facilitate processing of a substrate, an RF power generator 180 is optionally disposed adjacent to the window 134 to excite a gas from the first gas source 176, the second gas source 178, or both the first gas source 176 and the second gas source 178 to form an ionized species.

A purge gas source 185 is coupled to the interior volume 110 through a purge port 186 disposed through the lid assembly 108, between the window 134 and the upper blocker plate 142, and adjacent to the first plenum 171. The purge port 186 flows a gas, such as an inert gas, from the purge gas source 185 into the interior volume 110. In certain embodiments, the purge port 186 flows argon, nitrogen, or helium into the interior volume 110. Other purge gases are also contemplated. The purge gas facilitates removal of process gases from the processing chamber 100.

The faceplate 162 has a circular distribution portion 164 and an annular extension 166 disposed radially outward of the distribution portion 164. The annular extension 166 rests unfixed on an annular chamber liner 159 encircling the processing volume 115. Similarly, the chamber liner 159 rests unattached on the base 106 of the body 102. In other words, the faceplate 162 and the chamber liner 159 are not fixedly coupled to the processing chamber 100. The faceplate 162 and the chamber liner 159 remain movably seated in the processing chamber 100 to enable mechanical movement of the faceplate 162 and the chamber liner 159 during processing cycles. By allowing relative movement between the faceplate 162, the chamber liner 159, and the body 102, stress induced by thermal expansion or contraction of the faceplate 162 during processing cycles is relieved, thus preventing the faceplate 162 from cracking and/or warping due to thermal changes. Furthermore, because the faceplate 162 is not fixedly integrated with the processing chamber 100, the faceplate 162 bears no vacuum load when the processing chamber 100 is pumped down to high vacuum pressure and therefore does not suffer from vacuum stress.

In some embodiments, the faceplate 162 is coupled to a grounding element 184. The grounding element 184 may be a grounding wire coupled to the faceplate 162 and disposed through the sidewall 104. Other grounding element designs are also contemplated.

The faceplate 162 is generally formed from a thermally conductive material. In some embodiments, the faceplate 162 is formed from a metallic material, such as aluminum or stainless steel. In other embodiments, the faceplate 162 is formed from a ceramic material. For example, the faceplate 162 is formed from aluminum nitride or aluminum oxide. Any thermally conductive material may be used to form the faceplate 162. The chamber liner 159 is generally formed from a ceramic material. For example, the chamber liner 159 is formed from aluminum nitride, aluminum oxide, yttria, and other suitable ceramic materials. In certain embodiments, the chamber liner 159 is formed from quartz.

A third plurality of apertures 168 is disposed through the distribution portion 164 of the faceplate 162. The apertures 168 enable fluid communication between the third plenum 175 and the processing volume 115. In some embodiments, the apertures 168 are evenly distributed across the faceplate 162. In some embodiments, the apertures 168 are distributed with different spacing.

During operation, a process gas is permitted to flow from the first gas source 176 through the secondary channel 174 in the gas feed tube 170, and into the second plenum 173. Simultaneously or alternatively, a purge gas is flown from the purge gas source 185 through the purge port 186 and into the first plenum 171. From the first plenum 171, the purge gas passes through the apertures 148 in the upper blocker plate 142 and into the second plenum 173, where it mixes with the process gas supplied from the first gas source 176. The mixed gas then flows through the apertures 158 in the lower blocker plate 152 and into the third plenum 175. From the third plenum 175, the mixed gas flows through the apertures 168 in the faceplate 162 and into the process volume 115.

Simultaneously or alternatively, a cleaning gas is permitted to flow from the second gas source 178 through the central channel 172 in the gas feed tube 170, and into the third plenum 175. In the third plenum 175, the cleaning gas may be mixed with the mixed gas described above or either of the process gas or purge gas alone, and then flown through the apertures 168 and into the processing volume 115.

The arrangement and sizing of the apertures 148, 158, and 168 enables selective flow of the gas and purge gas into the process volume 115 in order to achieve a desired gas distribution. For example, a uniform distribution across the substrate W may be desired for certain processes. In certain embodiments, the number and/or size of the apertures 148 in the upper blocker plate 142 is lesser than that of the apertures 158 in the lower blocker plate 152. The reduced number and/or size of apertures 148 enables maintenance of a negative pressure delta between the first plenum 171 and the second plenum 173, wherein a higher pressure is maintained in the first plenum 171 compared to the second plenum 173. The negative pressure delta between the first plenum 171 and the second plenum 173 enables the utilization of less purge gas during operation, thus reducing the dilution of process or cleaning gases during processing. Further, the negative pressure delta prevents process and cleaning gases from flowing upstream through the gas distribution assembly 140 and depositing on the window 134, thus changing the transmissive properties of the window 134. In some embodiments, the pressure delta between the first plenum 171 and the second plenum 173 has a magnitude of between about 1 Torr and about 10 Torr, such as between about 2 Torr and about 8 Torr.

Also during operation, the radiant heat source 136 heats the gas distribution assembly 140 and in particular, the faceplate 162, to a predetermined temperature. In some embodiments, the upper blocker plate 142, the lower blocker plate 152, and the faceplate 162 are heated to a temperature of between about 200° C. and about 500° C., such as between about 250° C. and about 450° C. For example, the upper blocker plate 142, the lower blocker plate 152, and the faceplate 162 are heated to a temperature of between about 275° C. and about 300° C. Generally, a temperature delta between the window 134 and the upper blocker plate 142 has a magnitude of between about 100° C. and about 200° C. For example, the temperature delta between the window 134 and the upper blocker plate 142 has a magnitude of between about 120° C. and about 180° C., such as about 140° C. The increase in temperature of the gas distribution assembly 140, and more particularly, the faceplate 162, results in significantly less contaminant particle deposition on the substrate W during processing, such as CVD processes. Furthermore, in embodiments wherein the radiant heat source 136 includes a plurality of radiation sources 138 disposed in distinct heating zones, the faceplate 162 may be tunably heated to a desired temperature profile, thus enabling control of the deposition profile of the substrate W.

FIG. 1B illustrates a cross-section view of an enlarged portion of the processing chamber 100, according to one embodiment. Particularly, FIG. 1B depicts the lid assembly 108 coupled to the window 134, the upper blocker plate 142, and the lower blocker plate 152. Each of the window 134, the upper blocker plate 142, and the lower blocker plate 152 are disposed in a separate recess 190 around an internal surface of the annular lid assembly 108 (three recesses 190a-c are illustrated in FIG. 1B). One or more seals 182 are further disposed between one or more surfaces of each of the window 134, the upper blocker plate 142, and the lower blocker plate 152 and the recesses 190. For example, a first seal 182 may be disposed between an upper surface of each of the window 134, the upper blocker plate 142, and the lower blocker plate 152 and the recesses 190, and a second seal 182 may be disposed between a lower surface of each of the window 134, the upper blocker plate 142, and the lower blocker plate 152 and the recesses 190. In some embodiments, the seals 182 are formed from a material such as perfluoroelastomer (FFKM), polytetraflurorethylene (PTFE), rubber, or silicone. In some embodiments, the seals 182 are O-rings. Other seal designs, such as sheet gaskets or bonds, are also contemplated.

In some embodiments, the lid assembly 108 includes a first annular member 192, a second annular member 194, a third annular member 196, and a fourth annular member 198. The annular members 192, 194, 196, and 198 are detachable disks that clamp or fasten the window 134, the upper blocker plate 142, and the lower blocker plate 152 therebetween when assembled in a stacked configuration. In one embodiment, the annular members 192, 194, 196, and 198 are formed from a metallic material, such as stainless steel or aluminum. However, the annular members 192, 194, 196, and 198 may be formed of any material suitable for use with the process being performed therein.

As depicted in FIG. 1B, the first annular member 192 and the second annular member 194 form the recess 190a when coupled, enabling clamping of the window 134 therebetween. The second annular member 194 and the third annular member 196 form the recess 190b when coupled, enabling clamping of the upper blocker plate 142 therebetween. The third annular member 196 and the fourth annular member 198 form the recess 190c when coupled, enabling clamping of the lower blocker plate 152 therebetween.

Furthermore, one or more gas ports may be disposed through each of the annular members 192, 194, 196, and 198. For example, as depicted in FIG. 1B, the purge port 186 of the processing chamber 100 is disposed in the third annular member 196 and adjacent the first plenum 171, enabling the flow of purge gas from the purge gas source 185 into the first plenum 171. Although one gas port is depicted in the third annular member 196, additional or alternative gas ports may be disposed other annular members as well.

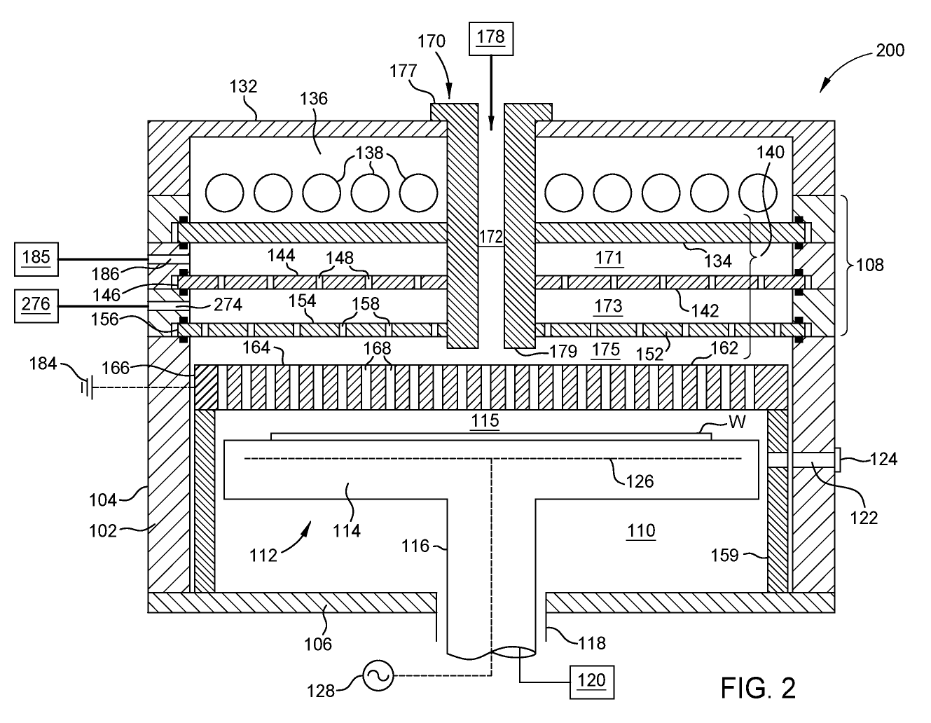

FIG. 2 illustrates a cross-sectional view of a processing chamber 200 according to one embodiment. The processing chamber 200 is similar to processing chamber 100, but includes a first gas source 276 coupled to the interior volume 110 through an inlet port 274, rather than the secondary channel 174 of the processing chamber 100. The inlet port 274 is disposed through the lid assembly 108 between the upper blocker plate 142 and the lower blocker plate 152, adjacent to the second plenum 173. Thus, the process gas is permitted to flow from the first gas source 276 through the inlet port 274 and directly into the second plenum 173. Similarly as described above, the process gas is mixed with the purge gas in the second plenum 173, and flown into the third plenum 175 before passing through the apertures 168 into the processing volume 115. In one embodiment, the inlet port 274 is disposed in the second annular member 194 of the lid assembly 108.

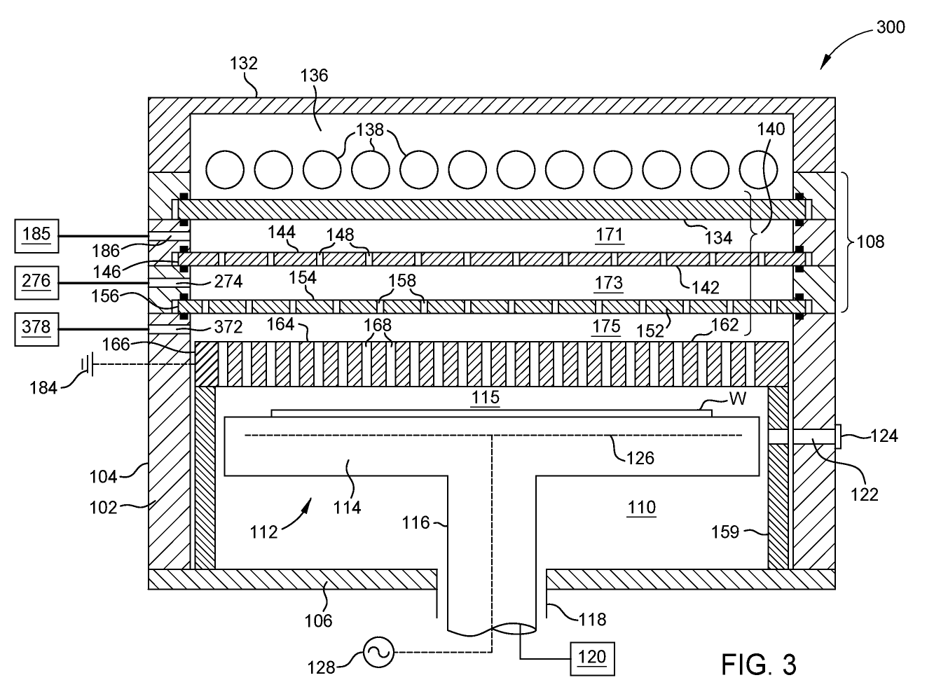

FIG. 3 illustrates a cross-sectional view of a processing chamber 300 according to one embodiment. The processing chamber 300 is similar to processing chambers 100 and 200, but the gas feed tube 170 has been removed. The first gas source 276 and a second gas source 378 are instead coupled to the interior volume 110 through inlet ports 274, 372, respectively, disposed in the lid assembly 108 and sidewall 104, respectively.

Similar to processing chamber 200, the first gas source 276 couples to the interior volume 110 through the inlet port 274 disposed in the lid assembly 108 between the upper blocker plate 142 and the lower blocker plate 152, adjacent to the second plenum 173. The second gas source 378, however, couples to the interior volume 110 through the second inlet port 372 disposed between the lower blocker plate 152 and the faceplate 162. Thus, cleaning gas is permitted to flow from the second gas source 378 through the second inlet port 372 and into the third plenum 175. During operation, as cleaning gas is flown through the second inlet port 372 and into the third plenum 175, the support shaft 116 is rotated to enable even spreading of the cleaning gas along surfaces of the substrate support 112 within the processing volume 115.

The embodiments described herein advantageously enhance gas flow uniformity and reduce the deposition of contaminant particles on a substrate by enabling the faceplate to be repeatedly heated to relatively higher temperatures while maintaining faceplate integrity. In conventional designs, a faceplate is generally not heated to the high temperatures as described herein because the faceplate would bow or warp due to thermal and vacuum load, in addition to the faceplate sealing materials degrading from thermal stress. By resting the faceplate on a chamber liner, wherein the faceplate and the chamber liner are not rigidly secured to one another or the chamber body, the faceplate is permitted to expand or compress during processing without sustaining damage induced by thermal stress, and outboard seals within the processing chamber remain isolated from the heated faceplate. Thus, thermal degradation of the outboard seals is reduced and a seal is maintained around the processing volume while the faceplate is heated to high temperatures. Furthermore, because the faceplate is not an integral structural component of the vacuum interface, the faceplate does not sustain damage caused by strain from a vacuum load in combination with the high thermal load.

Moreover, the embodiments described herein advantageously enable control of deposition profiles on the substrate. The utilization of a radiant energy source with distinct heating zones, wherein each heating zone is individually controlled to emit difference levels of radiation, enables tunability of the temperature profile the faceplate as well as the gases flown through the gas distribution apparatus, and thus, control of the deposition profile on the substrate.

While the foregoing is directed to embodiments of the present disclosure, other and further embodiments of the disclosure may be devised without departing from the basic scope thereof, and the scope thereof is determined by the claims that follow.

What is claimed is:

1. A gas distribution apparatus, comprising:
a lid assembly having a plurality of annular members disposed in a stacked arrangement;
a window coupled to the lid assembly, the window substantially transparent to electromagnetic radiation;
a first blocker plate coupled to the lid assembly and disposed adjacent to the window, the first blocker plate comprising a first plurality of apertures formed therethrough;
a second blocker plate coupled to the lid assembly and disposed adjacent to the first blocker plate, the second blocker plate comprising a second plurality of apertures formed therethrough, and wherein the first blocker plate and the second blocker plate are substantially transparent to electromagnetic radiation; and
a faceplate disposed on a chamber liner, the faceplate comprising a third plurality of apertures formed therethrough, the faceplate comprising a thermally conductive material.

2. The gas distribution apparatus of claim 1, wherein each of the first blocker plate and the second blocker plate couple to the lid assembly at annular extensions thereof, the annular extensions of the first blocker plate and the second blocker plate positioned between and in contact with respective annular members of the plurality of annular members.

3. The gas distribution apparatus of claim 1, wherein the plurality of annular members are detachable disks configured to fasten the window, the first blocker plate, and the second blocker plate therebetween when assembled in a stacked arrangement.

4. The gas distribution apparatus of claim 3, wherein the window, the first blocker plate, and the second blocker plate are disposed within recesses formed between each of the plurality of annular members.

5. The gas distribution apparatus of claim 4, wherein one or more seals are further disposed between one or more surfaces of each of the window, the first blocker plate, the second blocker plate, and the recesses.

6. The gas distribution apparatus of claim 2, wherein one or more gas ports are disposed through at least one annular member of the plurality of annular members.

7. The gas distribution apparatus of claim 6, wherein at least one gas port of the one or more gas ports is disposed in each of the plurality of annular members.

8. The gas distribution apparatus of claim 1, wherein the first blocker plate and the second blocker plate are formed of quartz.

9. The gas distribution apparatus of claim 1, wherein the first blocker plate and the second blocker plate are formed of different materials.

10. The gas distribution apparatus of claim 1, wherein the faceplate couples to the chamber liner at an annular extension of the face plate.

11. The gas distribution apparatus of claim 10, wherein the faceplate is unfixed to the chamber liner.

12. A gas distribution apparatus, comprising:
a lid assembly, the lid assembly having a plurality of annular members disposed in a stacked arrangement;
a window coupled to the lid assembly, the window substantially transparent to electromagnetic radiation;
a first blocker plate coupled to the lid assembly and disposed adjacent to the window, the first blocker plate comprising a first plurality of apertures formed therethrough;
a second blocker plate coupled to the lid assembly and disposed adjacent to the first blocker plate, the second blocker plate comprising a second plurality of apertures formed therethrough, and wherein the first blocker plate and the second blocker plate are substantially transparent to electromagnetic radiation;
a gas feed tube disposed through the window, the first blocker plate, and the second blocker plate, the gas feed tube having one or more channels disposed therethrough; and
a faceplate disposed on a chamber liner, the faceplate comprising a third plurality of apertures formed therethrough, the faceplate formed of a thermally conductive material.

13. The gas distribution apparatus of claim 12, wherein the gas feed tube includes a first channel formed from a first end of the gas feed tube to a second end of the gas feed tube and a second channel formed from the first end to a sidewall of the gas feed tube.

14. The gas distribution apparatus of claim 13, wherein two or more secondary channels are disposed radially outward of the first channel.

15. The gas distribution apparatus of claim 12, wherein the gas feed tube is formed of a ceramic material.

16. The gas distribution apparatus of claim 12, wherein the gas feed tube is centrally disposed through the window, the first blocker plate, and the second blocker plate.

17. An apparatus for processing a substrate, comprising:
a chamber, comprising:
a body having sidewalls and a base, the sidewalls and base partially defining an interior volume therein; and
a lid assembly coupled to the sidewalls opposite of the base, the lid assembly having a plurality of annular members disposed in a stacked arrangement;
a window coupled to the lid assembly and further defining the interior volume;
a radiant heat source disposed adjacent the window and external to the interior volume, the radiant heat source having a plurality of lamps;
a gas distribution assembly, comprising:
a first blocker plate coupled to the lid assembly and disposed adjacent to the window, the first blocker plate comprising a first plurality of apertures formed therethrough;
a second blocker plate coupled to the lid assembly and disposed adjacent to the first blocker plate, the second blocker plate comprising a second plurality of apertures formed therethrough, wherein the first blocker plate and the second blocker plate are substantially transparent to electromagnetic radiation; and
a faceplate disposed adjacent to the second blocker plate, the faceplate comprising a third plurality of apertures formed therethrough, the faceplate resting unfixed on a chamber liner and partially defining a processing volume therewith; and
a substrate support disposed through the base and into the processing volume.

18. The apparatus of claim 17, wherein the lamps are disposed in concentric rings around a central axis.

19. The apparatus of claim 18, wherein the concentric rings of lamps form distinct heating zones that are individually controllable to emit different levels of radiation.

20. The apparatus of claim 17, wherein the faceplate and the chamber liner are movably seated within the chamber.
